(19) United States
(12) Patent Application Publication
(10) Pub. No.: US 2005/0123070 A1
(43) Pub. Date: Jun. 9, 2005

(54) Clock offset compensation via signal windowing and non-data-aided (NDA) timing estimator

(75) Inventors: Wen-Ho Sheen, Hsinchu City (TW); Chii-Horng Chen, Hsinchu City (TW); Chien-Huci Lin, Hsinchu City (TW); Hsin-Hsiung Fang, Hsinchu City (TW)

Correspondence Address: SILICON VALLEY PATENT GROUP LLP, 2350 MISSION COLLEGE BOULEVARD, SUITE 360, SANTA CLARA, CA, 95054, US

(73) Assignee: Infineon-ADMtek Co., Ltd., Hsinchu City (TW)

(21) Appl. No.: 11/000,166

(22) Filed: Nov. 29, 2004

(30) Foreign Application Priority Data
Dec. 5, 2003 (TW) 092134484

(51) Int. Cl. H03K 9/00

(52) U.S. Cl. 375/316

(57) ABSTRACT

In the invention, a simple and robust method for clock offset compensation is proposed using an equalizer with time-varying signal windowing for which the timing information needed is obtained by an existing non-data-aided (NDA) timing estimator. Instead of interpolating the received signal, the proposed method compensates clock offset by using a moving signal window for equalizer. Since no interpolation is needed, the timing information required for the proposed method need not be so accurate as required for interpolation methods. Rather than the exact time drift due to clock offset, the proposed method requires only the timing points where the time drift accumulates to a pre-defined threshold. By applying an existing non-data-aided (NDA) timing estimator, the needed timing information can be obtained easily. Moreover, thanks to robustness of the NDA timing estimator, the proposed method is inherently robust and simple in implementation.

### FIELD OF THE INVENTION

The present invention relates to a method for clock offset compensation, especially a method for clock offset compensation via signal windowing and non-data-aided (NDA) timing estimator. It is mainly utilized in a communication system for compensating the clock offset between transmitter and receiver.

### BACKGROUND OF THE INVENTION

In a communication system, clock offset between transmitter and receiver is one of the RF imperfections, which usually degrades the overall system performance severely. Traditionally, in analog/hybrid timing recovery, the problem is solved by controlling the sampling instants (shifting a physical clock) using timing information from continuous-time/discrete-time signal so that the sampling instants are synchronous with the transmitter clock rate. However, in all-digital timing recovery, the synchronous samples are obtained (reconstructed) via interpolation using the asynchronous samples without shifting a physical clock. To achieve good performance, the above categories of timing recovery require extremely accurate timing information T[n]=nTs−nTt of the timing shift between the asynchronous sample instants from the associated synchronous sample instants (Ts and Tt denote the clock period of the receiver and transmitter, respectively). However, as accurate T[n] is rather difficult to be obtained, the performance of the above timing recovery approaches is unavoidably degraded due to the inaccurate timing information.

In wireless communication systems, a transmitted signal is usually distorted by intersymbol interference (ISI) due to multipath effects. Equalization is performed by an equalizer for mitigating the ISI. Several types of equalizer such as linear equalizer and decision feedback equalizer have been reported in the literature. One among them is the well-known finite impulse response (FIR) filter that has been widely used due to its stability and simplicity. An FIR equalizer of length L linearly combines L received discrete-time signals in a data window so that the filter output approximates the transmitted signal. With the linear time-varying channel caused by clock offset incorporated into the multipath channel, the resultant effective channel is also a linear time-varying channel. In the present invention, a novel approach is proposed for equalizing the time-varying channel (and thus equalizing the multipath channel and compensating for the clock offset simultaneously) that utilizes an FIR equalizer combining L received signals in a data window which moves according to the timing information. It is noted that the proposed approach does not explicitly compensate for the clock offset using an interpolator. Rather than requiring an accurate T[n], the proposed approach only needs the time instants at which the timing shift accumulates to a pre-defined threshold. By applying an existing non-data-aided (NDA) timing estimator, the needed timing information can be obtained easily. Moreover, thanks to robustness of the NDA timing estimator, the proposed method is inherently robust and simple in implementation.

In view of previous discussion, it is an object of the present invention to provide a method for clock offset compensation via signal windowing and non-data-aided (NDA) timing estimator.

### SUMMARY OF THE INVENTION

The main purpose of the present invention is to compensate the clock offset between transmitter and receiver of a communication system. The timing information needed for the present method is obtained by the NDA timing estimator. Further, the signal window for the equalizer moves according to the timing information.

Let r₂[n]=r(t=nTs/2) be the discrete-time received signal where r(t) is the received continuous-time signal and e[n] be the output of FIR filter (equalizer) v[n] of length L, that is,

$$e [ n ] = {\sum }_{k = 0}^{L - 1} v [ k ] \cdot {r}_{2} [ 2 n - k + I [ n ] ] n = 0 , 1 , 2 , 3 \qquad ( 1 )$$

Note that I[n] is a time-varying integer. The filter v[n] is the so-called fractionally-spaced (T/2-spaced) linear equalizer that combines L received signals r[2n+I[n]]={r₂[2n−L+I[n]+1], r₂[2n−L+I[n]+2], . . . , r₂[2n+I[n]]} (data window of length L). The goal of equalization is to obtain v[n] such that the resultant signal e[n] approximates the desired signal d[n] (usually the transmitted signal). This can be achieved by minimizing a cost function such as the well-known minimum mean square error (MMSE) criterion as follows,
J=E[|e[n]−d[n]|2] (2)

It is noted that the L signals in r[2n+I[n]] should highly correlate with the desired signal d[n] to achieve good performance for equalization and a corresponding small J. In other words, I[n] must be chosen so that the following correlation function is large.
E[r₂*[2n−i+I[n]]d[n]],i=0, 1, . . . ,L−1 (3)

The initial value I[0] can be decided by adjusting the decision delay through simulation such that the correlations in (3) are large. However, as the receiver clock period Ts is smaller (larger) than the transmitter clock period Tt, the sampled signal r₂[n]=r(t=nTs/2)==r(t=n′Tt/2), where n′ is smaller (larger) than n. Accordingly, the correlation strength of desired signal d[n] and r[2n+I[0]] fade away gradually from the right (left) side of the window. Thus, as Ts is smaller (larger) than Tt, I[n] should be an increasing (decreasing) function so that r[2n+I[n]] can “track” the desired signal d[n] and thus high correlation of both can be maintained. Since the sampling period is Ts/2, the update of I[n] (increased or decreased by an integer number) can be performed step-wise as the timing shift |T[n]|=|nTs−nTt | reaches multiples of Ts/2. Specifically, as the timing shift T[n]=nTs−nTt exceeds kTs/2 (the duration of k instants), I[n] should be updated by I[0]−k. Similarly, as the timing shift T[n]=nTs−nTt is smaller than −kTs/2, I[n] should be updated by I[0]+k. That is, I[n] can be updated as follows,
I[n]=I[0]−sign(T[n])·k,(k+1)Tₛ/2>|T[n]|≧kTₛ/2 (4)

For updating I[n], one needs to decide sign(T[n]) and detect the time instants nᵢₖ that satisfy the following formula.
(k+1)Tₛ/2>|T[nᵢₖ]|≧kTₛ/2,∀k>0,nᵢ₁<nᵢ₂<nᵢ₃< (5)

Equivalently, the information of sign(T[n]) and time instants nᵢₖ are sufficient for the update of I[n] by (4). For the former, sign(T[n]) is constant (either 1 or −1) due to constant Ts and Tt and to decide sign(T[n]) is nothing but to decide the faster/slower of the receiver clock rate compared to transmitter clock rate. Finally, let us present an existent NDA timing parameter estimator which can be used to detect nᵢₖ and the sign of T[n]. With the help of the timing estimator, the update of I[n] can be achieved by a very simple procedure.

Let r₄[n]=r(t=nTs/4) be the oversampled received signal. Let c[n]=Re{c[n]}+j Im{c[n]} be a complex sequence obtained from r₄[n] given by

$$Re \{ c [ n ] \} = {\sum }_{m = - M}^{M} {\vert {r}_{4} [ 4 n + m ] \vert}^{2} - {\vert {r}_{4} [ 4 n + m + 2 ] \vert}^{2} , n = 0 , 1 , 2 , 3 \\ Im \{ c [ n ] \} = {\sum }_{m = - M}^{M} {\vert {r}_{4} [ 4 n + m + 3 ] \vert}^{2} - {\vert {r}_{4} [ 4 n + m + 1 ] \vert}^{2} , n = 0 , 1 , 2 , 3 \qquad ( 6 )$$

where Re{c[n]} and Im{c[n]} are real and imaginary parts of c[n], respectively.

Note that M is a parameter for length of averaging. Note also that c[0] could be an arbitrary complex number depending on the received signal. Please refer to FIG. 1. While it can be shown that in the absence of noise, the angle arg{c[n]} has the following three properties:

It is uniformly distributed over [0˜2π] as n increases;

It is a periodic function with period N satisfying |T(N)|=Ts; and

It rotates in clock-wise direction for Ts<Tt, and in counter clock-wise direction for Ts>Tt.

By (5) and the above-mentioned second property, one can detect nᵢₖ as the point such that arg{c[nᵢₖ]} is close to arg{c[0]}+kπ for integer k. For simplicity, arg{c[0]} can be mapped to the nearest angle in the sets {0, π/2, π, 3π/2}. By the above-mentioned third property, the sign of T[n] can be decided by detecting the direction of rotation of arg{c[n]}. For ease of latter use, denote the four points {1, j, −1, j} as four references 1, 2, 3 and 4 whose phases are equal to the four phases {0, π/2, π, 3π/2}. Let us summarize the update procedure of I[n] as follows,
(S1): Calculate c[0] and then obtain the nearest reference r. Set two thresholds η₁ and η₂.
(S2): Monitor the values of c[n], n=0, 1, 2, 3 . . .

(i) If the number of c[n] counted in the [mod(r+1,4)]th quadrant is larger than η₁ and at least one point of c[n] is detected in the [mod(r+2,4)]th quadrant, update I[n] by I[n]−1 and reference r by mod(r+2,4). Update n by n+1.

Note that C=mod(A,B) denotes a modified remainder. C is remainder of A divided by B if the remainder is not equal to zero. If the remainder is zero, C=B.

(ii) If the number of c[n] counted in the [mod(r+2,4)]th quadrant is larger than η₂ and at least one point of c[n] is detected in the [mod(r+1,4)]th quadrant, update I[n] by I[n]+1 and reference r by mod(r+2,4). Update n by n+1.

(iii) Otherwise, update n by n+1 and go to (i).

In (S2), as the number of c[n] in the [mod(r+1,4)]th ([mod(r+2,4)]th) quadrant is larger than η₁ (η₂), then the rotation of arg{c[n]} is detected as in counter clock-wise (clock-wise) direction. Whereas detection of at least one c[n] in the [mod(r+2,4)]th ([mod(r+1,4)]th) quadrant indicates that the angle of rotation from the previous reference to the detected point is π. Finally, let us concludes with some advantages of the proposed method as follows:
(A1): The noise effects in c[n] can be significantly suppressed by increasing the averaging window length 2M+1.
(A2): Given c[n], the monitoring procedure in (S2) is very simple with only comparators required.
(A3): The accumulation of number of c[n] in either [mod(r+1,4)]th or [mod(r+2,4)]th quadrant performs some kind of averaging that reduces the false detection of nᵢₖ due to inaccurate estimates of c[n].

In conclusion, a novel approach has been proposed for equalizing the time-varying channel (due to clock offset effect and multipath channel) without explicitly compensating for the clock offset using an interpolator. The data window processed by the FIR equalizer moves according to the parameter I[n] given by (4). With the help of the NDA timing estimator, the update procedure of I[n] exhibits some advantages and becomes very simple.

It is one object of the present invention to provide a method for clock offset compensation utilizing signal windowing and non-data-aided timing estimator. The proposed method does not explicitly compensate for the clock offset effect using an interpolator. Rather than requiring an accurate T[n], the proposed approach merely requires an easily attainable timing information of the time instants at which the timing shift accumulates to a pre-defined threshold. By applying an existing NDA timing estimator for obtaining the required timing information for the proposed method, the resultant timing estimator is inherently robust and becomes very simple in implementation.

According to one aspect of the present invention, a method for clock offset compensation utilizing signal windowing and a non-data-aided (NDA) timing estimator, comprising the steps of: (a) operating an oversampled received signal by the non-data-aided (NDA) timing estimator to generate a complex sequence; (b) setting a first, a second, a third, a fourth and a fifth parameters; (c) operating the complex sequence to generate a value into the second parameter; (d) adding a value of the first parameter to a value of a third parameter to generate a resultant value, and then changing the value of the first parameter into the resultant value; (e) if an item having a first ordinal number of the complex sequence which is equal to the value of the first parameter has a first value, wherein the first value is located in a first quadrant of the complex plane with a first relationship to the second parameter, adding 1 to a value of the fourth parameter and then performing step (g); (f) if the first value is located in a second quadrant of the complex plane with a second relationship to the second parameter, adding 1 to a value of the fifth parameter and then performing step(g); (g) if the first value is located in the second quadrant of the complex plane with the second relationship to the second parameter, and the value of the fourth parameter exceeds a first threshold value, then changing the value of the fourth parameter into zero; changing the value of the fifth parameter to zero; changing the value of the second parameter into a first numeral which is equal to a second ordinal number of the second quadrant in the complex plane; subtracting 1 from the first value; and returning back to the step (d); (h) if the first value is located in the first quadrant of the complex plane with the first relationship to the second parameter, and the value of the fifth parameter exceeds a second threshold value, then changing the value of the fourth parameter into zero; changing the value of the fifth parameter into zero; changing the value of the second parameter into a second numeral which is equal to a third ordinal number of the first quadrant of the complex plane; adding 1 to the first value; and returning back to the step (d).

Preferably, the value of the first parameter is an integer with an initial value of zero.

Preferably, the value of the third parameter is a positive integer.

Preferably, the first quadrant of the complex plane with a first relationship to the second parameter is determined by a first modified remainder of dividing the value of the second parameter having been added by 1 by 4.

Preferably, the second quadrant of the complex plane with the second relationship to the second parameter is determined by a second modified remainder of dividing the value of the second parameter having been added by 2 by 4.

Preferably, the step (f) is performed before performing the step (e).

Preferably, the step (h) is performed before performing the step (g).

The foregoing and other features and advantages of the present invention will be more clearly understood through the following descriptions with reference to the drawings, wherein:

### BRIEF DESCRIPTION OF THE DRAWINGS

FIG. 1 is a diagram illustrating the moving process of c[n] on the complex plane; and

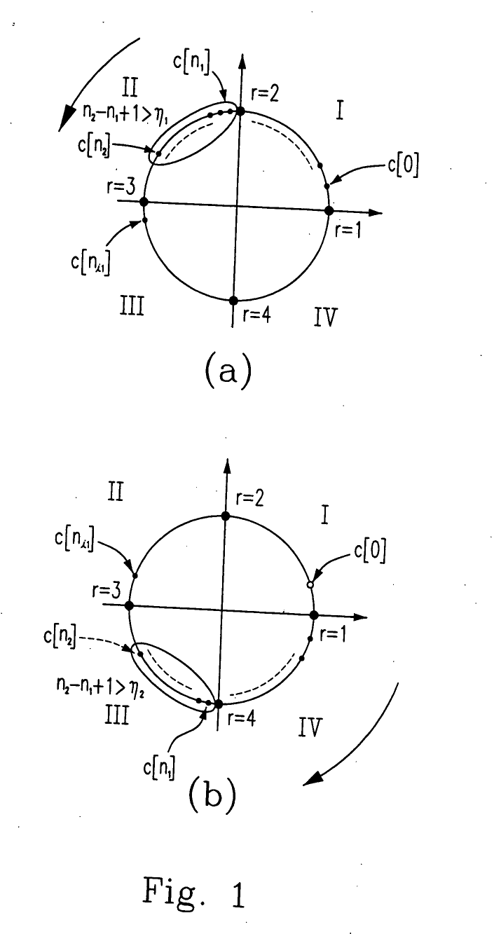

FIG. 2 is a flow chart for determining the parameter I[n].

### DETAILED DESCRIPTION OF THE PREFERRED EMBODIMENT

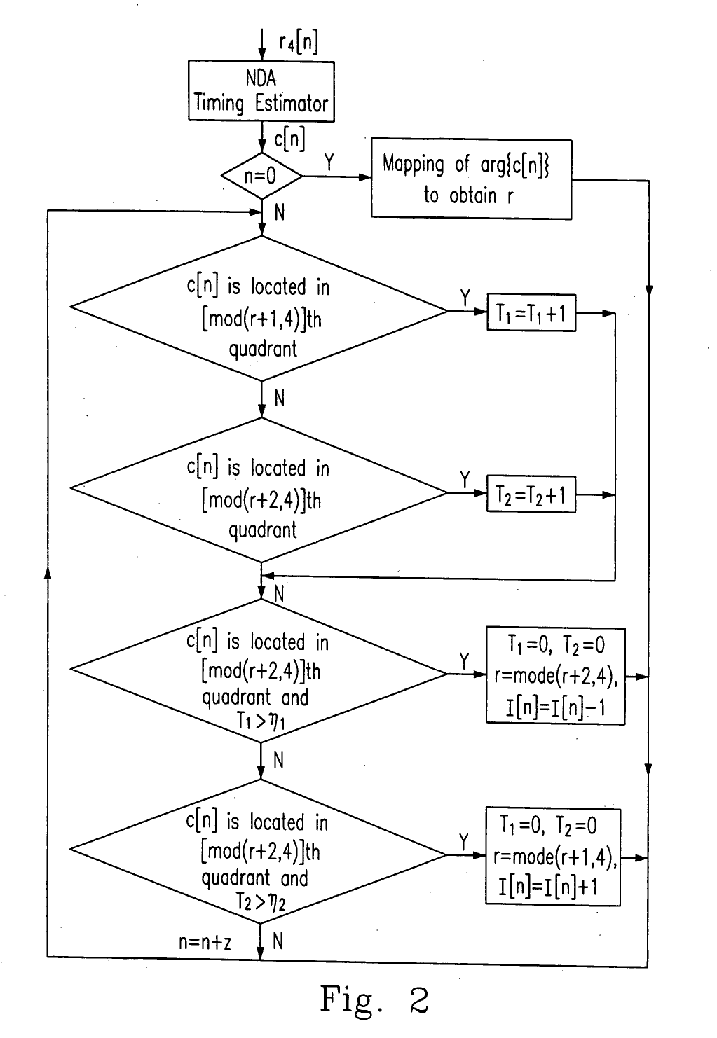

FIG. 2 is the flow chart of the present invention for illustrating the method of determining the parameter I[n] for clock offset compensation. According to FIG. 2, first, a non-data-aided (NDA) timing estimator is used to process an oversampled received signal r₄[n] and then a complex sequence c[n] is obtained. Next, n is checked to be zero or not. If n is zero, a reference r is induced, if not, then determine whether the nth number of the complex sequence c[n] is located in the Ath quadrant of the complex plane where A is equal to mod(r+1,4). If the nth number of the complex sequence c[n] is located in the Ath quadrant of the complex plane, the parameter T₁ is added by 1, if not, then determine whether the nth number of the complex sequence c[n] is located in the Bth quadrant of the complex plane where B is equal to mod(r+2,4). If the nth number of the complex sequence c[n] is located in the Bth quadrant of the complex plane, the parameter T₂ is added by 1. If the nth number of the complex sequence c[n] is located neither in the Ath quadrant nor in the Bth quadrant, then determine whether the nth number of the complex sequence c[n] is located in the Bth quadrant and whether T₁ exceeds a first threshold number η₁. If this is true, set the values of T₁ and T₂ to zero, the value of reference r to the cardinal number of Bth (i.e., if the Bth quadrant stands for the second quadrant, the reference r is set to be 2), subtract the nth number of the parameter sequence I[n] by 1, add n by z as a new n, and repeat the foregoing steps. The parameter z is a positive integer. However, if this is not true, determine whether the nth number of the complex sequence c[n] is located in the Ath quadrant and whether T₂ exceeds a second threshold number η₂. If this is true, set the values of T₁ and T₂ to zero, the value of reference r to the cardinal number of Bth, add the nth number of the parameter sequence I[n] by 1, add z to n to be a new n, and repeat the foregoing steps. Again, z is a positive integer. If this is not true, add n by z as a new n, and repeat the foregoing steps until all numbers of c[n] are calculated. That is, determine whether the next number of the complex sequence c[n] is located in the Ath quadrant . . .

In summary, according to the above-mentioned steps, the timing information used for moving a data window can be obtained by utilizing non-data-aided (NDA) timing estimator. By following the present method, the required timing information is easily obtained compared with the prior art methods such as interpolator. Therefore, in a communication system, the clock offset between transmitter and receiver and the multipath channel can be effectively compensated by the proposed method.

While the invention has been described in terms of what is presently considered to be the most practical and preferred embodiments, it is to be understood that the invention needs not be limited to the disclosed embodiments. On the contrary, it is intended to cover various modifications and similar arrangements included within the spirit and scope of the appended claims which are to be accorded with the broadest interpretation so as to encompass all such modifications and similar structures.

1. A method for clock offset compensation utilizing signal windowing and a non-data-aided (NDA) timing estimator, comprising the steps of:
a) processing an oversampled received signal by said non-data-aided (NDA) timing estimator to generate a complex sequence;
b) setting a first, a second, a third, a fourth and a fifth parameters;
c) operating said complex sequence to generate a value into said second parameter;
d) adding a value of said first parameter to a value of a third parameter to generate a resultant value, and then changing said value of said first parameter into the resultant value;
e) if an item having a first ordinal number of said complex sequence which is equal to said value of said first parameter has a first value, wherein said first value is located in a first quadrant of the complex plane with a first relationship to said second parameter, adding 1 to a value of said fourth parameter and then performing step (g);
f) if said first value is located in a second quadrant of said complex plane with a second relationship to said second parameter, adding 1 to a value of said fifth parameter and then performing step (g);
g) if said first value is located in said second quadrant of said complex plane with said second relationship to said second parameter, and said value of said fourth parameter exceeds a first threshold value, then
changing said value of the fourth parameter into zero;
changing said value of said fifth parameter to zero;
changing said value of said second parameter into a first numeral which is equal to a second ordinal number of said second quadrant in the complex plane;
subtracting 1 from said first value; and
returning back to said step (d);
h) if said first value is located in said first quadrant of said complex plane with said first relationship to said second parameter, and said value of said fifth parameter exceeds a second threshold value, then
changing said value of said fourth parameter into zero;
changing said value of said fifth parameter into zero;
changing said value of said second parameter into a second numeral which is equal to a third ordinal number of said first quadrant of said complex plane;
adding 1 to said first value; and
returning back to said step (d).

2. The method as claimed in claim 1, wherein said value of said first parameter is an integer with an initial value of zero.

3. The method as claimed in claim 1, wherein said value of said third parameter is a positive integer.

4. The method as claimed in claim 1, wherein said first quadrant of said complex plane with a first relationship to said second parameter is determined by a first modified remainder of dividing said value of said second parameter having been added by 1 by 4.

5. The method as claimed in claim 1, wherein said second quadrant of said complex plane with said second relationship to said second parameter is determined by a second modified remainder of dividing said value of said second parameter having been added by 2 by 4.

6. The method as claimed in claim 1, wherein said step (f) is performed before performing said step (e).

7. The method as claimed in claim 1, wherein said step (h) is performed before performing said step (g).
